(19) United States
(12) Patent Application Publication
(10) Pub. No.: US 2022/0068757 A1
(43) Pub. Date: Mar. 3, 2022

(54) Thermal Coupling Between Transistor And Audio Drivers With Heat Sink

(71) Applicant: Juliano Anflor, Gravatai (BR)

(72) Inventor: Juliano Anflor, Gravatai (BR)

(21) Appl. No.: 17/421,681

(22) PCT Filed: Jul. 9, 2019
(86) PCT No.: PCT/BR2019/050261

§ 371 Date: Jul. 8, 2021

(51) Int. Cl. H01L 23/373

(52) U.S. Cl. CPC H01L 23/3735

(57) ABSTRACT

The invention refers to the thermal coupling between the SMD transistor/audio driver and a heat sink, wherein said thermal coupling consists of placing, below the SMD transistor or audio driver, a plate with thermal conductive material core capable of eliminating deficiencies of the state of the art. The SMD transistor or audio driver (1) is welded directly to the top of the plate with thermal conductive material core (2), which promotes heat transfer to a heat sink (3) that is welded directly to the bottom of the plate with thermal conductive material core. This design provides an optimal heat transfer, since the transistor or audio driver (1) is welded directly, through an oven weld remelting process, to a highly thermally conductive material. The transistors and drivers are welded directly to the plate through a highly thermally conductive dielectric material used in its construction, the installation of the plate with thermal conductive material core in the sink is facilitated, as it eliminates the need to employ electrical insulators and fasteners such as screws and clamps.

### TECHNOLOGICAL SECTOR OF THE INVENTION

The present invention belongs, in general, to the technological sector of electronic devices and refers, more specifically, to the audio amplifier sector, with the purpose of improving the thermal coupling between SMD (surface mount device) transistor and audio drivers with their heat sinks, reducing the working temperature and thus allowing the increase of the power density of audio amplifiers, reduced product cost and increased reliability, while eliminating fastening and electrical insulation components between the plate and the sink, reducing product manufacturing time, dimensions and cost.

### KNOWN STATE OF THE ART

The state of the art of this technological sector comprises two modalities of transistor encapsulation for audio amplifiers, namely the PTH (pin through-hole) and the SMD (surface mount device).

The PTH components are mounted directly on the heat sink through screws, fasteners and electrical insulator, so they have a proper thermal coupling. However, fastening is expensive, slow to assembly and takes up a lot of space.

The current SMD components are welded directly to the printed circuit board (PCB), which is made of fiberglass with low thermal conductivity. To make the thermal transfer between the SMD component and a heat sink coupled underneath the printed circuit board (PCB), “pathways” are used just below the transistor, which are copper-metallized holes having the function of providing the electrical/thermal connection between one side and the other of the PCB board. In this arrangement, the thermal coupling is adversely affected due to the fact that the “pathways” do not have good thermal conductivity, since the thickness of copper metallization is very thin, which causes the SMD component to operate at a higher temperature in relation to the PTH components. A 0.6 mm pathway has an average thermal resistance of 96.8° C./W, which means that with each watt dissipated in the component, its temperature will rise by 96.8° C. The addition of more pathways reduces thermal resistance, but this solution is limited by the reduced size of the transistor or audio driver. In 270 mm² of plate with as many pathways as possible, the thermal resistance drops to 12° C./W. To exemplify, in an audio amplifier of 100 W and 90% efficiency, there is a power of 10 W dissipated in the transistor or audio driver that needs to be transferred to the heat sink and the pathways do not give the thermal conduction appropriate to this application. In this example, the component would reach 120° C. dissipating a power of 10 W, and most transistors have a maximum working temperature of 150° C. Another disadvantage refers to the need to use electrical insulator between the plate and the sink.

In this context, document U.S. Pat. No. 6,828,170, published on Jan. 10, 2002, discloses a semiconductor optical radiation package including a frame, at least one semiconductor optical radiation emitter and one encapsulant. The frame has a heat extraction member, which supports the semiconductor optical emitter and provides one or more thermal paths to remove the heat generated within the emitter into the environment, as well as at least two electrical conductors to provide electrical coupling to the optical radiation of the emitter semiconductor. The encapsulant covers and protects the emitter and optional cables from damage and allows radiation to be emitted from the emitter into the environment. However, said document does not disclose the use of dielectric at the interface between the plate and the SMD component, therefore not electrically isolating it; furthermore, said document does not point to the sink installation on the opposite side of the board relative to the SMD component.

Document US 2002/0109544, published on Aug. 15, 2002, discloses a musical amplifier that includes a vacuum valve and a transistor. The vacuum tube is connected to the transistor port so that the current flow through the transistor is controlled by the vacuum tube. According to one example of the invention, the vacuum-transistor tube arrangement is configured in a “push-pull” arrangement, where a combination of vacuum-transistor tube controls positive voltages, and another vacuum-transistor tube combination controls the negative stresses delivered by the system, the system output being at approximately zero voltage when not under load. Said document does not provide a technical solution to reduce the size of boards with SMD components and prevent overheating. The deficiency in the state of the art is therefore obvious, and the technical solution to such, proposed by the present invention, is described below.

### NOVELTY AND OBJECTIVES OF THE INVENTION

The present invention refers to an improved thermal coupling between the SMD transistor/audio driver and a heat sink, wherein said thermal coupling consists of placing, below the SMD transistor/audio driver, a core plate of thermal conductive material capable of eliminating deficiencies of the state of the art. Thus, the present invention comprises the replacement of the core of printed circuit boards, originally produced with epoxy compounds and/or fiber boards, by a core consisting of a material with compatible thermal conductivity, such as aluminum, copper or ceramic. Such replacement allows the transistor or audio driver to have a direct thermal coupling with the heat sink by direct welding it to the plate with metal core and a heat transfer equivalent to the PTH components. Since transistors and drivers are welded directly to the plate with thermal conductive material core, electrically insulated between the thermal conductive material core and the transistor through a highly thermally conductive dielectric material used in its construction, the installation of the plate with thermal conductive material core in the sink is facilitated, as it eliminates the need to use electrical insulators and fasteners such as screws and clamps (required in PTH components).

The advantages of the invention are multifold, among which the following stand out. By changing the printed circuit boards (PCBs) used in the state of the art for a thermal conductive material core plate, the SMD component will operate at a lower temperature, increasing the reliability of the product, since the maximum working power of the transistor or driver is inversely proportional to its operating temperature (FIG. 1). In this way, it is also possible to use a smaller and cheaper power component, ensuring the same reliability in the application. This dissipation enhancement feature will therefore allow audio amplifiers to be manufactured with a smaller size than those available in the state of the art.

In some cases, the thermal conductive material plate can replace the heat sink, as it is made of the same material as heat sinks and can assume the same function.

### DESCRIPTION OF THE ACCOMPANYING DRAWINGS

In order for the present invention to be fully understood and put into practice by any person skilled in the art, it will be explained in a clear, concise and sufficient manner, based on the accompanying drawings listed below, which are only examples of preferred embodiments without having the purpose of limiting the scope of the invention only to the examples illustrated, because anyone skilled in the art knows that countless changes, deletions, additions and substitutions can be made without straying from the scope of protection:

FIG. 1 presents a typical curve of maximum operating current versus temperature of a transistor available in the state of the art.

FIG. 2 presents a device arrangement available in the current state of the art, illustrating an SMD transistor or audio driver mounted on a standard fiberglass plate with thermal transfer pathways.

FIG. 3 presents the proposed invention, in which the SMD transistor or audio driver is welded on a plate with thermal conductive material core with heat transfer to a sink.

FIGS. 4 and 5 show comparisons between 1200 W amplifier used in the state of the art (left) and 1200 W amplifier according to the present invention, with smaller dimensions (right).

FIGS. 6 and 7 show comparisons between 800 W amplifier used in the state of the art (left) and 800 W amplifier according to the present invention, with smaller dimensions (right).

### DETAILED DESCRIPTION OF THE INVENTION

The invention comprises an SMD transistor or audio driver (1) welded directly on top of a plate with thermal conductive material core (2), said plate with thermal conductive material core promoting heat transfer to a sink (3), said sink being welded directly to the bottom of the plate with thermal conductive material core. This design provides an optimal heat transfer, since the transistor or audio driver (1) is welded directly, through an oven weld remelting process, to a highly thermally conductive material.

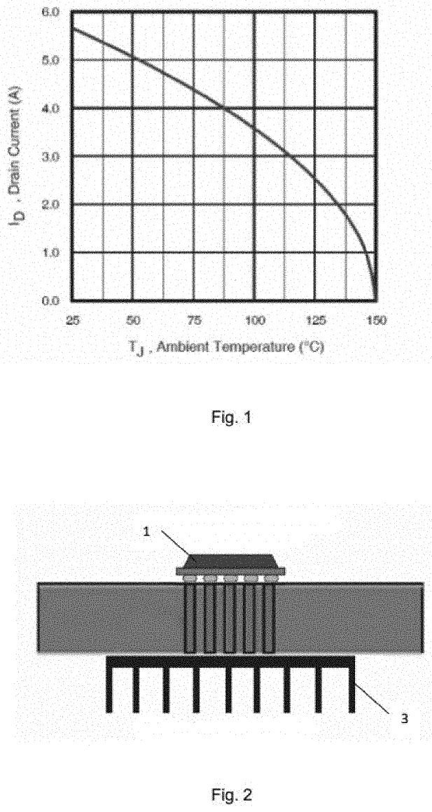

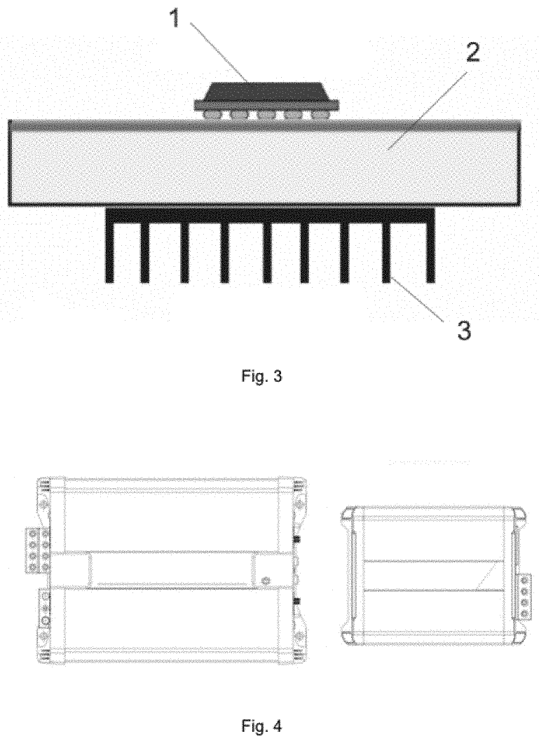

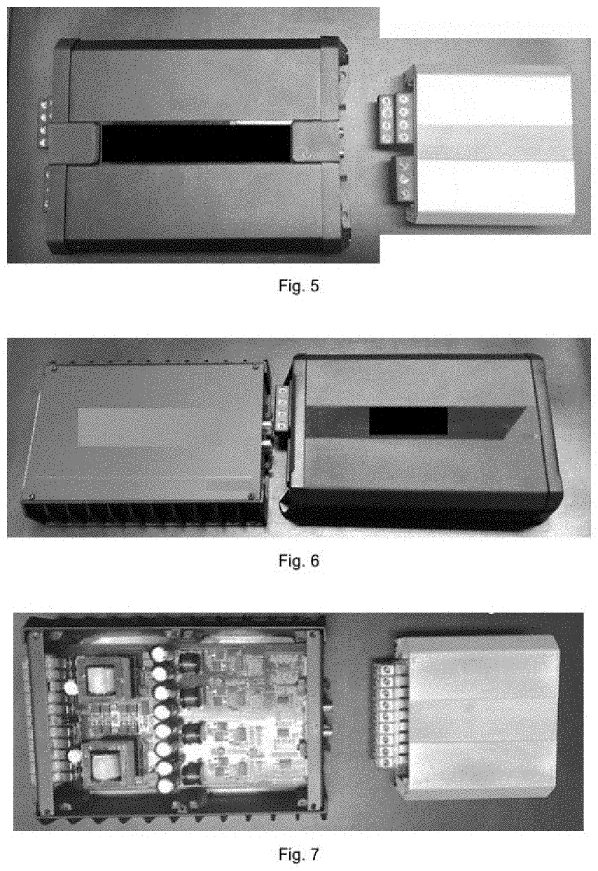

In a preferred embodiment of the invention, a plate (2) with aluminum, copper or ceramic core is used. FIG. 1 shows the typical curve of maximum operating current versus temperature of a transistor and, as previously explained, with the components installed conventionally on a 270 mm² plate, an audio amplifier of 100 Wand 90% efficiency will present a power of 10 W dissipated in the transistor or audio driver that needs to be transferred to the heat sink, raising the temperature of the mounted component by 120° C. In the same area of 270 mm², with the components installed according to the present invention, the thermal resistance of a plate with thermal conductive material core (2) is only 0.2° C./W and a component (2) that dissipates the same 10 W would raise its temperature by only 2° C.

Two prototypes were assembled according to the invention, one with an 800 W amplifier and the other with a 1200 W amplifier, both equipped with a plate with thermal conductive material core. In the 800 W amplifier, the power density (Watt/cm³) increased around 2×, and in the 1200 W amplifier, the power density increased by around 3×, reducing the dimensions of the end product in the same proportion, compared to those known to date, showing the great improvement that the proposed patent offers to the product, since the reduction of the plate and sink size result in a large cost reduction. The two prototypes reached the specified power and had thermal performance, power and durability equivalent or better than the products without the use of the improvements cited in the invention.

In the example disclosed in FIG. 4, there is a comparison between a conventional 1200 W amplifier and one employing the present technology. The conventional amplifier has dimensions of 7.1 cm by 10.5 cm. The amplifier according to the present invention has dimensions of 5 cm by 7 cm. Both allow the proper operation of the amplifier of 1200 W, remaining at low temperatures, evidencing the technical effect obtained by the present invention, which allowed a reduction of 53% in the dimensions of the amplifier.

The present specification refers to an invention endowed with industrial application, novelty and inventive step, thus satisfying all the legal requirements to receive the patent sought.

What is claimed is:

1. A thermal coupling between transistor and audio drivers with heat sink comprising surface mount device (SMD) transistor or audio driver, plate and heat sink, wherein said plate has a thermal conductive material core, said SMD transistor or audio driver is welded on top of said plate with thermal conductive material core and electrically insulated from said plate with thermal conductive material core through a dielectric, and said heat sink is welded at the bottom of said plate with thermal conductive material core.

2. The thermal coupling between transistor and audio drivers with heat sink according to claim 1, wherein said plate with thermal conductive material core has a core chosen from the group consisting of: aluminum, copper, or ceramic.

3. The thermal coupling between transistor and audio drivers with heat sink according to claim 1, wherein said SMD transistor or audio driver is welded to said metal core plate via an oven weld remelting process.

4. The thermal coupling between transistor and audio drivers with heat sink according to claim 1, wherein the thermal resistance of the plate with thermal conductive material core is 0.2° C./W.
